(19) United States
(12) Patent Application Publication
(10) Pub. No.: US 2014/0017863 A1
(43) Pub. Date: Jan. 16, 2014

(54) METHODS OF MANUFACTURING SEMICONDUCTOR DEVICES INCLUDING METAL GATES

(71) Applicant: Samsung Electronics Co., Ltd., Suwon-si (KR)

(72) Inventors: Yoon-Seok Lee, Seoul (KR); Yoon-Hae Kim, Suwon-si (KR); Hong-Seong Kang, Hwaseong-si (KR); Sung-Ho Son, Hwaseong-si (KR); JunJie Xiong, Suwon-si (KR); You-Shin Choi, Seoul (KR)

(21) Appl. No.: 13/918,475

(22) Filed: Jun. 14, 2013

(30) Foreign Application Priority Data
Jul. 16, 2012 (KR) 10-2012-0077216

(51) Int. Cl. H01L 29/66

(52) U.S. Cl. CPC H01L 29/66477
USPC 438/238

(57) ABSTRACT

Methods of manufacturing a semiconductor device including metal gates are provided. The method may include forming a resistor pattern and a dummy gate electrode, which include polysilicon, and forming an impurity region adjacent to the dummy gate electrode. The method may further include replacing the dummy gate electrode with a gate electrode and then forming metal silicide patterns on the resistor pattern and the impurity region.

### CROSS-REFERENCE TO RELATED APPLICATION

This U.S. non-provisional patent application claims priority under 35 U.S.C. §119 to Korean Patent Application No. 10-2012-0077216, filed on Jul. 16, 2012 in the Korean Intellectual Property Office, the disclosure of which is hereby incorporated by reference in its entirety.

### FIELD

The present disclosure generally relates to the field of electronics and, more particularly, to integrated circuit devices.

### BACKGROUND

Gate electrodes including metal patterns instead of polysilicon patterns may be used to improve performance of integrated circuit devices but the peripheral regions of the devices may include polysilicon patterns, for example, in resistor pattern or fuse pattern.

### SUMMARY

A method of manufacturing a semiconductor device may include forming a resistor pattern and a dummy gate electrode on a substrate. The resistor pattern and the dummy gate electrode may include doped polysilicon. The method may further include forming an impurity region at an upper portion of the substrate adjacent to the dummy gate electrode. The method may also include replacing the dummy gate electrode with a gate electrode and then forming first and second metal silicide patterns on the resistor pattern and the impurity region, respectively.

In various embodiments, replacing the dummy gate electrode with the gate electrode may include forming a first insulating interlayer on the resistor pattern and the dummy gate electrode on the substrate, removing the dummy gate electrode to form a first opening through the first insulating interlayer and forming the gate electrode on the exposed upper surface of the substrate in the first opening. The first opening may expose an upper surface of the substrate and the gate electrode may include metal.

According to various embodiments, forming the first and second metal silicide patterns may include forming a second insulating interlayer on the first insulating interlayer, the resistor pattern and the gate electrode and forming second and third openings exposing the resistor pattern and the impurity region, respectively. The second opening may extend through the second insulating interlayer and the third opening may extend through the first and second insulating interlayers. Forming the first and second metal silicide patterns may further include forming a metal layer on the exposed resistor pattern and the impurity region and performing a silicidation process in which the metal layer reacts with the resistor pattern and the impurity region.

According to various embodiments, forming the first and second metal silicide patterns may also include forming first and second contact structures in the second and third openings respectively

In various embodiments, additionally the method may include forming a high-k dielectric layer pattern on a bottom surface and a sidewall of the first opening prior to forming the gate electrode. The high-k dielectric layer pattern may extend on a bottom surface and a sidewall of the gate electrode.

In various embodiments, the method may include forming a fuse pattern on the substrate and forming a third metal silicide pattern on the fuse pattern. The fuse pattern may include doped polysilicon and forming the first insulating interlayer may include forming the first insulating interlayer on the fuse pattern.

According to various embodiments, forming the first, second and third metal silicide patterns may include forming a second insulating interlayer on the first insulating interlayer, the resistor pattern, the gate electrode and the fuse pattern and forming second and third openings exposing the resistor pattern and the fuse pattern respectively and a fourth opening exposing the impurity region. The second and third openings may extend through the second insulating interlayer and the fourth opening may extend through the first and second insulating interlayers. Additionally, forming a metal layer on the exposed resistor pattern, the impurity region and the fuse pattern and performing a silicidation process in which the metal layer reacts with the resistor pattern, the impurity region and the fuse pattern may be included.

Moreover, forming a third insulating interlayer on the second insulating interlayer to fill the second, third and fourth openings, forming a fifth opening through the first, second and third insulating interlayers to expose the impurity region and forming a first contact structure in the fifth opening may be included. Still further forming a fourth insulating interlayer on the third insulating interlayer and the first contact structure and forming sixth and seventh openings exposing the resistor pattern and the fuse pattern, respectively, and an eighth opening exposing the first contact structure and forming second, third and fourth contact structures in the sixth, seventh and eighth openings respectively may be included. The sixth and seventh openings may extend through the second, third and fourth insulating interlayers and the eighth opening may extend through the fourth insulating interlayer

According to various embodiments, the first, second, third and fourth insulating interlayers may include a same material.

In various embodiments, the method may include performing a selective epitaxial growth (SEG) process using an upper portion of the impurity region as a seed layer to form an elevated source drain (ESD) layer on the impurity region. Forming the second metal silicide pattern may include forming the second metal silicide pattern on the ESD layer.

A semiconductor device may include a resistor pattern including doped polysilicon on a substrate in a first region and a gate structure on the substrate in a second region. The gate structure may include a gate electrode including metal and a high-k dielectric layer pattern on a bottom surface and a sidewall of the gate electrode. The device may further include an impurity region at an upper portion of the substrate adjacent to the gate structure and first and second metal silicide patterns on the resistor pattern and the impurity region respectively.

In various embodiments, the device may also include a fuse pattern including doped polysilicon on the substrate in a third region.

In various embodiments, the device may include a third metal silicide pattern on the fuse pattern.

According to various embodiments, the device may include an ESD layer on the impurity region. The second metal silicide pattern may be disposed on the ESD layer.

According to various embodiments, the device may further include first and second contact structures on the first and second metal silicide patterns respectively. Bottom surfaces of the first and second contact structures may be disposed in areas same as or within areas where top surfaces of the first and second metal silicide patterns are disposed respectively.

A method of manufacturing an integrated circuit device may include forming a polysilicon pattern on a substrate in a first region, forming a gate structure on the substrate in a second region and forming an impurity region on the substrate adjacent to the gate structure. Then the method may further include forming an insulating interlayer on the polysilicon pattern, the gate structure and the impurity region and forming first and second openings extending through the insulating interlayer and exposing surfaces of the polysilicon pattern and the impurity region, respectively. The method may also include forming first and second metal silicide patterns on the surfaces of the polysilicon pattern and the impurity region exposed by the first and second openings, respectively.

In various embodiments, forming the gate structure may include forming the gate structure including a metal gate electrode.

In various embodiments, forming the gate structure may include forming a dummy gate electrode on the substrate in the second region and forming a first insulating interlayer on the dummy gate electrode. The first insulating interlayer may expose an upper surface of the dummy gate electrode. Additionally, removing the dummy gate electrode to form a gate opening in the first insulating layer and forming a metal gate electrode in the gate opening may be included. The second opening may extend through the first insulating interlayer.

According to various embodiments, forming the dummy gate electrode may include forming a polysilicon layer on the substrate in the first and second regions and patterning the polysilicon layer to form the dummy gate electrode and the polysilicon pattern.

According to various embodiments, the method may also include forming a high-k dielectric layer pattern conformally on a portion of the first insulating interlayer defining the gate opening prior to forming the metal gate electrode therein. The high-k dielectric layer pattern may extend between the first insulating interlayer and the metal gate electrode.

In various embodiments, forming the first and second metal silicide patterns may include forming a metal layer contacting the surfaces of the polysilicon pattern and the impurity region exposed by the first and second openings respectively and performing a heat treatment to form the first and second metal silicide patterns through reactions of the metal layer with the polysilicon pattern and the impurity region, respectively.

According to various embodiments, forming the impurity region may include forming an elevated impurity region protruding from an upper surface of the substrate on the impurity region. Forming the second metal silicide pattern may include forming the second metal silicide pattern in the elevated impurity region.

In various embodiments, the method may also include forming an isolation layer in a field region on the substrate and the polysilicon pattern may extend over the isolation layer.

In various embodiments, the method may include forming an insulating pattern on the isolation layer and the insulating pattern may contact the isolation layer.

According to various embodiments, the second opening may expose a portion of the surface of the polysilicon pattern and cover a remaining portion of the surface of the polysilicon pattern.

### BRIEF DESCRIPTION OF THE DRAWINGS

FIG. 1 is a cross-sectional view illustrating a semiconductor device in accordance with some embodiments;

FIG. 2 is a cross-sectional view illustrating a semiconductor device in accordance with some embodiments;

FIGS. 3 to 10 are cross-sectional views illustrating a method of manufacturing a semiconductor device in accordance with some embodiments;

FIG. 11 is a cross-sectional view illustrating a semiconductor device in accordance with some embodiments;

FIG. 12 is a cross-sectional view illustrating a semiconductor device in accordance with some embodiments; and

FIGS. 13 to 20 are cross-sectional views illustrating a method of manufacturing a semiconductor device in accordance with some embodiments.

### DETAILED DESCRIPTION

Example embodiments are described below with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout.

Example embodiments of the inventive concepts are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, example embodiments of the inventive concepts should not be construed as limited to the particular shapes illustrated herein but include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, integers, steps, operations, elements, and/or components, but do not preclude the presence or addition of one or more other features, integers, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

It will be understood that although the terms first, second, etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein may be interpreted accordingly.

FIG. 1 is a cross-sectional view illustrating a semiconductor device in accordance with some embodiments.

Referring to FIG. 1, the semiconductor device may include a resistor structure 142, a gate structure 210, an impurity region 105, an elevated source drain (ESD) layer 160, and first and second metal silicide patterns 232 and 234 on a substrate 100.

The semiconductor device may further include first and second contact structures 272 and 274 on the first and second metal silicide patterns 232 and 234, respectively, and third and fourth contact structures 312 and 314 on the first and second contact structures 272 and 274, respectively.

The substrate 100 may be a semiconductor substrate, e.g., a silicon substrate, a germanium substrate, a silicon-germanium substrate, a silicon on insulator (SOI) substrate, a germanium on insulator (GOI) substrate, etc. The substrate 100 may be divided into a field region in which an isolation layer 110 is formed, and an active region in which no isolation layer is formed. Additionally, the substrate 100 may include a first region I and a second region II. In some embodiments, resistors may be formed in the first region I, and active devices for forming circuits may be formed in the second region II.

The resistor structure 142 may be formed on the substrate 100 in the first region I.

In some embodiments, the resistor structure 142 may be formed on the field region of the substrate 100, i.e., on the isolation layer 110. In FIG. 1, one resistor structure 142 is shown, however, a plurality of resistor structures 142 may be formed in the first region I.

The resistor structure 142 may include a first insulation layer pattern 122 and a resistor pattern 132 sequentially stacked on the substrate 100 in the first region I.

In some embodiments, the first insulation layer pattern 122 may include, e.g., silicon oxide, and the resistor pattern 132 may include doped polysilicon.

A first spacer 152 may be formed on a sidewall of the resistor structure 142. The first spacer 152 may include, e.g., silicon nitride.

The gate structure 210 may include a high-k dielectric layer pattern 190 and a gate electrode 200 sequentially stacked on the substrate 100 in the second region II. A second insulation layer pattern may be further formed between the substrate 100 and the high-k dielectric layer pattern 190. The second insulation layer pattern may include, e.g., silicon oxide.

In some embodiments, the high-k dielectric layer pattern 190 may cover a bottom and a sidewall of the gate electrode 200. In some embodiments, the high-k dielectric layer pattern 190 may include a metal oxide, e.g., hafnium oxide, tantalum oxide, zirconium oxide, etc., and the gate electrode 200 may include a low resistance metal, e.g., aluminum, copper, tungsten, etc.

In FIG. 1, one gate structure 210 is shown, however, a plurality of gate structures 210 may be formed on the substrate 100 in the second region II.

A second spacer 154 may be formed on a sidewall of the gate structure 210. The second spacer 154 may include, e.g., silicon nitride. In some embodiments, the second spacer 154 may include a material, which is included in the first spacer 152.

The impurity region 105 may be formed on the active region of the substrate 100 adjacent to the gate structure 210. In some embodiments, the impurity region 105 may include single crystalline silicon-germanium doped with p-type impurities, e.g., boron, or single crystalline silicon carbide doped with n-type impurities, e.g., arsenic.

The ESD layer 160 may be formed on the impurity region 105 and contact the second spacer 154, and include single crystalline silicon doped with impurities of a conduction type, which is the same as that of the impurity region 105 therebeneath. The ESD layer 160 may include single crystalline silicon doped with p-type impurities, e.g., boron, or single crystalline silicon doped with n-type impurities, e.g., arsenic.

When the impurity region 105 and the ESD layer 160 include p-type impurities, the gate structure 210, the impurity region 105 and the ESD layer 160 may provide a p-channel metal oxide semiconductor (PMOS) transistor, and when the impurity region 105 and the ESD layer 160 include n-type impurities, the gate structure 210, the impurity region 105 and the ESD layer 160 may provide an n-channel metal oxide semiconductor (NMOS) transistor. That is, the impurity region 105 together with the ESD layer 160 may serve as a source/drain region of a transistor.

An etch stop layer 170 may be formed on sidewalls of the first and second spacers 152 and 154, a sidewall and a top surface of the ESD layer 160, a top surface of the isolation layer 110 and a top surface of the substrate 100. In some embodiments, the etch stop layer 170 may include silicon nitride. In some embodiments, the etch stop layer 170 may not be formed.

The outer sidewalls of the first and second spacers 152 and 154 on the sidewalls of the resistor structure 142 and the gate structure 210, respectively, and the sidewall and the top surface of the ESD layer 160 may be covered by a first insulating interlayer 180 on the etch stop layer 170. The first insulating interlayer 180 may include, e.g., silicon oxide.

The first metal silicide pattern 232 may be formed on a top surface of the resistor pattern 132 and the second metal silicide pattern 234 may be formed on a top surface of the ESD layer 160. In an example embodiment, the first metal silicide pattern 232 may be formed on end portions of the resistor pattern 132, and the second metal silicide pattern 234 may be formed on a top surface of the impurity region 105 through the ESD layer 160.

In some embodiments, the first and second metal silicide patterns 232 and 234 may include a metal silicide, e.g., nickel silicide, cobalt silicide, platinum silicide, etc.

As appreciated by the present inventors, the high temperature processes, e.g., the formation of the impurity region 105, the formation of the ESD layer 160, the formation of the gate structure 210, etc., may damage the metal silicide patterns 232 and 234 if those are formed before the high temperature processes. According to some embodiments, since the first and second metal silicide patterns 232 and 234 are formed after the high temperature processes, damage to the first and second metal silicide patterns 232 and 234 caused by the high temperature processes may be reduced, and accordingly, the device may have good electrical characteristics.

A second insulating interlayer 220 may be formed on the first insulating interlayer 180, the resistor structure 142 and the gate structure 210. The second insulating interlayer 220 may include, e.g., silicon oxide. In some embodiments, the second insulating interlayer 220 may include a material, which is included in the first insulating interlayer 180.

The first contact structure 272 may be formed on the first metal silicide pattern 232 through the second insulating interlayer 220. The first contact structure 272 may be aligned with the first metal silicide pattern 232. Thus, a bottom surface of the first contact structure 272 may contact a top surface of the first metal silicide pattern 232, and the bottom surface of the first contact structure 272 may be disposed in an area same as or within an area where the top surface of the first metal silicide pattern 232 is disposed, if viewed in plan view. In some embodiments, the first contact structure 272 may include a first conductive layer pattern 262 and a first barrier layer pattern 252 on a sidewall and a bottom surface of the first conductive layer pattern 262.

The second contact structure 274 may be formed on the second metal silicide pattern 234 through the first and second insulating interlayers 180 and 220 and the etch stop layer 170. The second contact structure 274 may be aligned with the second metal silicide pattern 234. Thus, a bottom surface of the second contact structure 274 may contact a top surface of the second metal silicide pattern 234, and the bottom surface of the second contact structure 274 may be disposed in an area same as or within an area where the top surface of the second metal silicide pattern 234 is disposed, if viewed in plan view. In some embodiments, the second contact structure 274 may include a second conductive layer pattern 264 and a second barrier layer pattern 254 on a sidewall and a bottom surface of the second conductive layer pattern 264.

In some embodiments, the first and second conductive patterns 262 and 264 may include the same material, e.g., doped polysilicon, a metal, a metal nitride and/or a metal silicide. In some embodiments, the first and second barrier layer patterns 252 and 254 may include the same material, e.g., a metal or a metal nitride.

A third insulating interlayer 280 may be formed on the second insulating interlayer 220 and the first and second contact structures 272 and 274. The third insulating interlayer 280 may have a single layer or a plurality of layers sequentially stacked on each other. The third insulating interlayer 280 may include a material, which is included in the first and second insulating interlayers 180 and 220.

The third and fourth contact structures 312 and 314 may be formed on the first and second contact structures 272 and 274, respectively, through the third insulating interlayer 280. In some embodiments, the third contact structure 312 may include a third conductive layer pattern 302 and a third barrier layer pattern 292 on a sidewall and a bottom surface of the third conductive layer pattern 302, and the fourth contact structure 314 may include a fourth conductive layer pattern 304 and a fourth barrier layer pattern 294 on a sidewall and a bottom surface of the fourth conductive layer pattern 304.

In some embodiments, the third and fourth conductive layer patterns 302 and 304 may include the same material, e.g., doped polysilicon, a metal, a metal nitride and/or a metal silicide. In some embodiments, the third and fourth barrier patterns 292 and 294 may include the same material, e.g., a metal or a metal nitride.

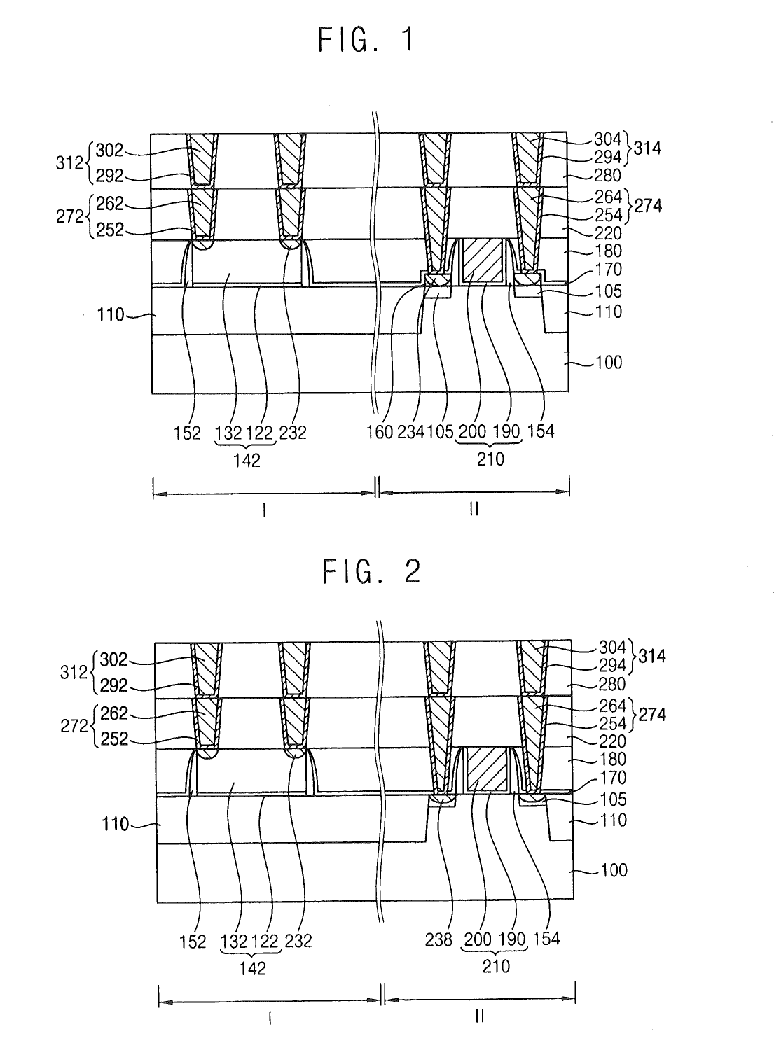

FIG. 2 is a cross-sectional view illustrating a semiconductor device in accordance with some embodiments.

Referring to FIG. 2, the semiconductor device may include a resistor structure 142, a gate structure 210, an impurity region 105, and first and fourth metal silicide patterns 232 and 238. The semiconductor device may further include first and second contact structures 272 and 274 on the first and fourth metal silicide patterns 232 and 238, respectively, and third and fourth contact structures 312 and 314 on the first and second contact structures 272 and 274, respectively.

The semiconductor device may not include an ESD layer and may have the fourth metal silicide pattern 238 on impurity region 105.

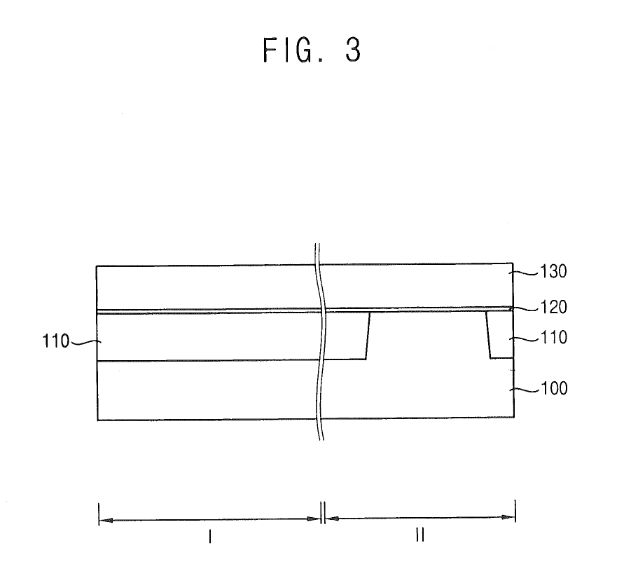

FIGS. 3 to 10 are cross-sectional views illustrating a method of manufacturing a semiconductor device in accordance with some embodiments.

Referring to FIG. 3, after forming an isolation layer 110 on a substrate 100, an insulation layer 120 and a polysilicon layer 130 may be sequentially formed on the substrate 100 and the isolation layer 110.

The substrate 100 may include a field region in which the isolation layer 110 is formed, and an active region in which no isolation layer is formed. In some embodiments, the isolation layer 110 may be formed by a shallow trench isolation (STI) process. The substrate 100 may include a first region I and a second region II. In some embodiments, resistors may be formed in the first region I, and active devices of circuits, e.g., transistors may be formed in the second region II.

The insulation layer 120 may be formed by a chemical vapor deposition (CVD) process, an atomic layer deposition (ALD) process, etc., using silicon oxide. The polysilicon layer 130 may be also formed by a CVD process, an ALD process, etc.

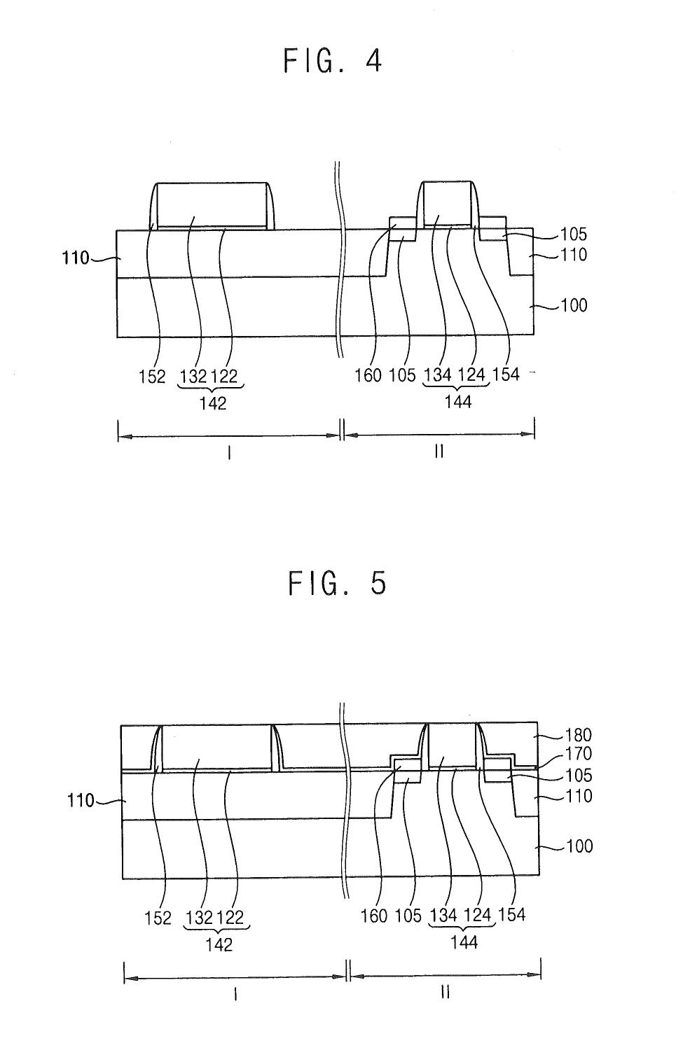

Impurities may be implanted into the polysilicon layer 130. In some embodiments, the impurities may be implanted by an ion implantation process. During the ion implantation process, the concentration of the impurities may be adjusted so that a resistor pattern 132 (refer to FIG. 4) subsequently formed may have a desired resistance.

Referring to FIG. 4, the polysilicon layer 130 and the insulation layer 120 may be patterned by a photolithography process to form a resistor structure 142 including a first insulation layer pattern 122 and a resistor pattern 132 sequentially stacked on the substrate 100 in the first region I, and a dummy gate structure 144 including a second insulation layer pattern 124 and a dummy gate electrode 134 sequentially stacked on the substrate 100 in the second region II. In some embodiments, the resistor structure 142 may be formed in the field region of the substrate 100, i.e., on the isolation layer 110. In FIG. 4, only one resistor structure 142 and only one dummy gate electrode 144 are shown, however, a plurality of resistor structures 142 and a plurality of dummy gate electrodes 144 may be also formed.

A spacer layer covering the resistor structure 142 and the dummy gate structure 144 may be formed on the isolation layer 110 and the substrate 100, and patterned by an anisotropic etching process to form a first spacer 152 on a sidewall of the resistor structure 142 and a second spacer 154 on a sidewall of the dummy gate structure 144. In some embodiments, the spacer layer may include silicon nitride by a CVD process, an ALD process, etc.

An impurity region 105 may be formed at an upper portion of the active region of the substrate 100 adjacent to the dummy gate structure 144, and an ESD layer 160 may be formed on the impurity region 105.

After a photoresist pattern covering the first region I of the substrate 100 is formed, an upper portion of the active region of the substrate 100 in the second region II may be removed using the photoresist pattern, the dummy gate structure 144 and the second spacer 154 as an etching mask to form a trench. Then the impurity region 105 filling the trench may be formed.

In some embodiments, a first selective epitaxial growth (SEG) process using a top surface of the substrate 100 exposed by the trench as a seed may be performed to form the impurity region 105. In an example embodiment, the first SEG process may be performed at a temperature of about 500° C. to about 900° C. under a pressure of about 0.1 Torr to a normal pressure, i.e., about 1 atm or 760 Torr.

The first SEG process may be performed using dichlorosilane gas, germane gas, etc., as a source gas, so that a single crystalline silicon-germanium layer may be formed. In the first SEG process, p-type impurity source gas, e.g., diborane gas may be used also to form a single crystalline silicon-germanium layer doped with p-type impurities. Thus, the impurity region 105 of a positive-channel metal oxide semiconductor (PMOS) transistor may be formed.

Alternatively, the first SEG process may be performed using disilane gas and SiH₃CH₃ gas, etc., as a source gas, so that a single crystalline silicon carbide layer may be formed. In the first SEG process, n-type impurity source gas, e.g., phosphine gas may be used also to form a single crystalline silicon-germanium layer doped with n-type impurities. Thus, the impurity region 105 of a negative-channel metal oxide semiconductor (NMOS) transistor may be formed.

In some embodiments, the first SEG process may include the formation of both of the impurity region of the PMOS transistor and the impurity region of the NMOS transistor.

A second SEG process may be performed to form the ESD layer 160. The second SEG process may be performed using the impurity region 105 as a seed. In an example embodiment, the second SEG process may be performed at a temperature of about 500° C. to about 900° C. under a pressure of about 0.1 Torr to a normal pressure, i.e., about 1 atm or 760 Torr.

The second SEG process may be performed using dichlorosilane gas and a p-type impurity source gas, e.g., diborane gas, so that a single crystalline silicon layer doped with p-type impurities may be formed. Alternatively, the second SEG process may be performed using dichlorosilane gas and an n-type impurity source gas, e.g., phosphine gas, so that a single crystalline silicon layer doped with n-type impurities may be formed.

In some embodiments, the first SEG process for forming the impurity region 105 and the second SEG process for forming the ESD layer 160 may be formed in-situ. That is, when the impurity region 105 is formed, a silicon source gas, a germanium source gas and a p-type impurity source gas may be provided to perform an SEG process, and the germanium source gas may not be provided to form the ESD layer 160. Alternatively, when the impurity region 105 is formed, a silicon source gas, a carbon source gas and an n-type impurity source gas may be provided to perform an SEG process, and the carbon source gas may not be provided to form the ESD layer 160.

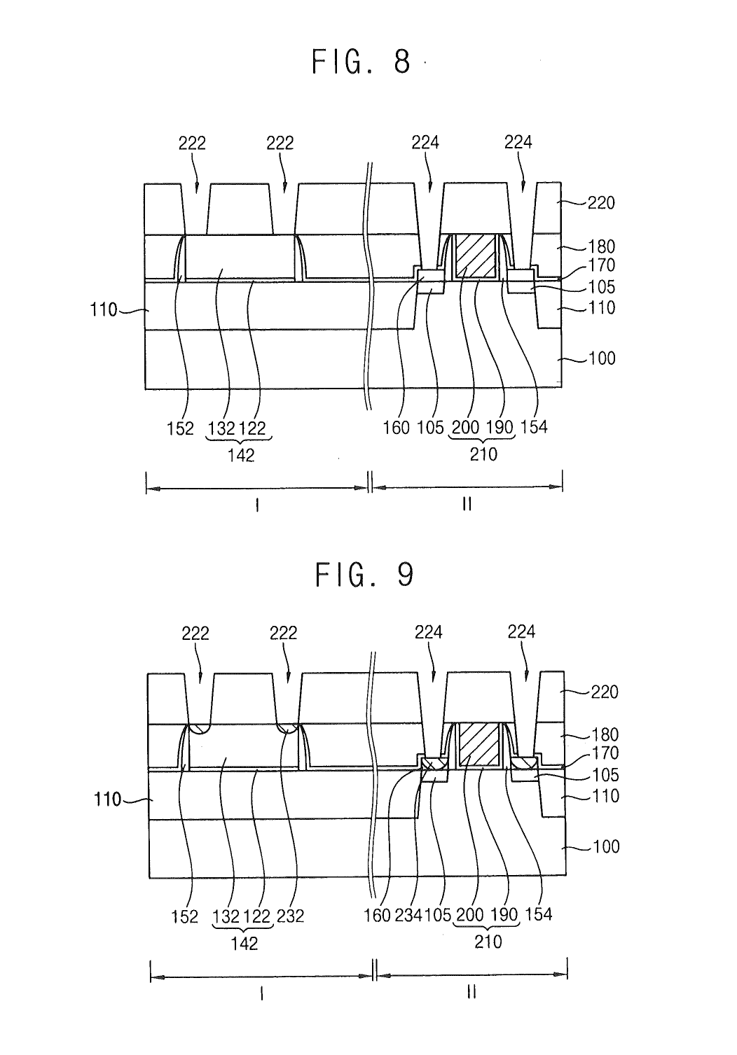

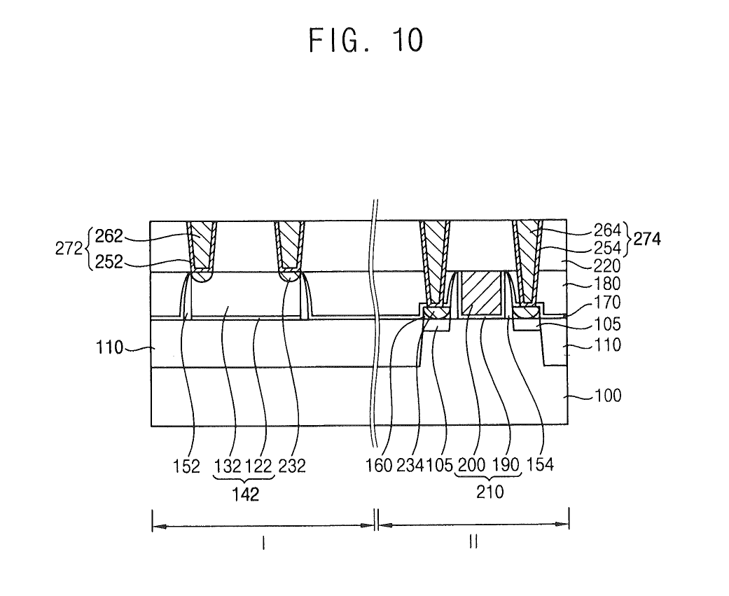

The formation of the ESD layer 160 may be optional, thus it may be skipped. When the ESD layer 160 is not formed, a third opening 224 (refer to FIG. 8) subsequently formed may expose a top surface of the impurity region 105 instead of a top surface of the ESD layer 160, a fourth metal silicide layer pattern 238 (refer to FIG. 2) may be formed on the impurity region 105 instead of the second metal silicide pattern 234 on the ESD layer 160, and a second contact structure 274 (refer to FIG. 10) filling the third opening 224 may be formed to contact a top surface of the fourth metal silicide pattern 238 instead of a top surface of the second metal silicide pattern 234.

Referring to FIG. 5, after an etch stop layer 170 is formed on the resistor structure 142, the dummy gate structure 144, the first and second spacers 152 and 154 and the ESD layer 160, a first insulating interlayer 180 may be formed on the etch stop layer 170 to have a height sufficient to cover the resistor structure 142, the dummy gate structure 144, the first and second spacers 152 and 154 and the ESD layer 160, and the first insulating interlayer 180 and the etch stop layer 170 may be planarized until top surfaces of the resistor structure 142 and the dummy gate structure 144 may be exposed.

In some embodiments, the etch stop layer 170 may include silicon nitride, and the first insulating interlayer 180 may include silicon oxide. In some embodiments, the planarization process may be performed by a chemical mechanical polishing (CMP) process.

The formation of the etch stop layer 170 may be optional, thus it may be skipped.

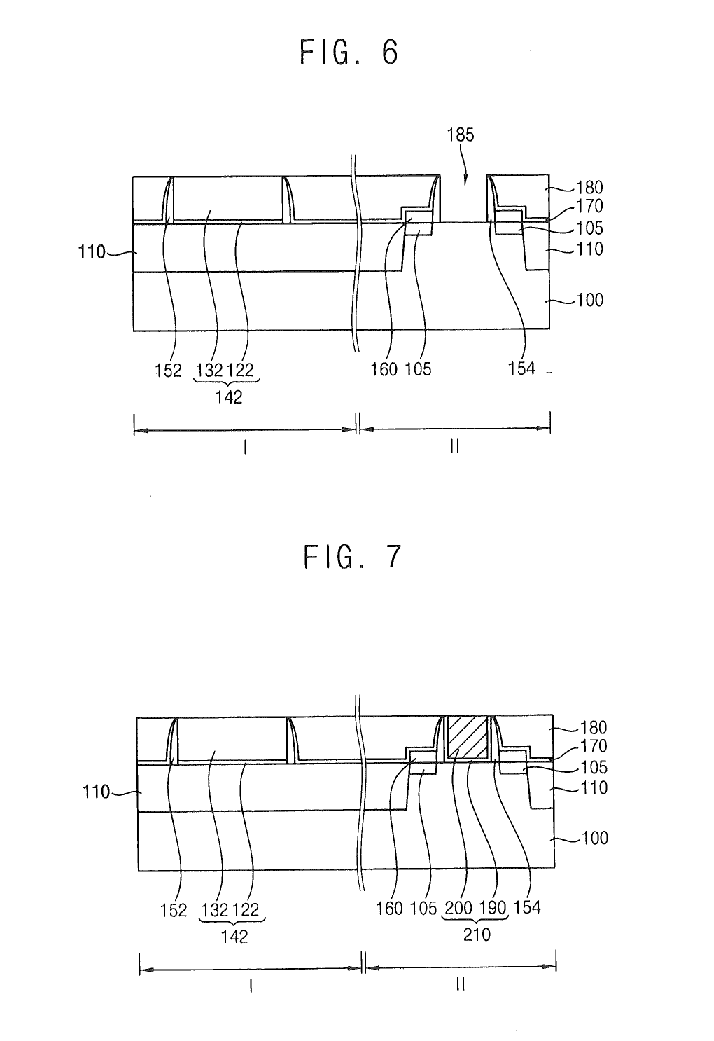

Referring to FIGS. 6 and 7, the dummy gate structure 144 may be replaced by a gate structure 210.

Referring to FIG. 6, the exposed dummy gate structure 144 may be removed to form a first opening 185 exposing a top surface of the substrate 100. That is, the first opening 185 may be defined by an inner wall of the second spacer 154. The dummy gate structure 144 may be removed by a wet etching process or a dry etching process. The second insulation layer pattern 124 of the dummy gate structure 144 may not be removed.

Referring to FIG. 7, a high-k dielectric layer pattern 190 may be formed on the exposed top surface of the substrate 100 and a sidewall of the first opening 185, and a gate electrode 200 filling a remaining portion of the first opening 185 may be formed.

A high-k dielectric layer may be formed on the exposed top surface of the substrate 100, the inner wall of the first opening 185, the top surface of the first insulating interlayer 180 and the top surface of the resistor structure 142, and a gate electrode layer sufficiently filling a remaining portion of the first opening 185 may be formed on the high-k dielectric layer.

The high-k dielectric layer may include a metal oxide having a high dielectric constant, e.g., hafnium oxide, tantalum oxide, zirconium oxide, etc. The gate electrode layer may include a low resistance metal, e.g., aluminum, copper, tantalum, etc., or a metal nitride formed by an ALD process or a physical vapor deposition (PVD) process. A heat treatment process, e.g., a rapid thermal annealing (RTA) process, a spike RTA process, a flash RTA process or a laser annealing process may be further performed on the gate electrode layer.

The gate electrode layer and the high-k dielectric layer may be planarized until a top surface of the first insulating interlayer 180 may be exposed to form a high-k dielectric layer pattern 190 on the top surface of the substrate 100 and the inner wall of the first opening 185, and a gate electrode 200 filling the remaining portion of the first opening 185 on the high-k dielectric layer pattern 190. In some embodiments, the planarization process may be performed by a CMP process.

Thus, the gate structure 210 including the high-k dielectric layer pattern 190 and the gate electrode 200 may be formed, and a second spacer 154 may be formed on a sidewall of the gate structure 210. The high-k dielectric layer pattern 190 may serve as a gate insulation layer, and when the second insulation layer pattern 124 is not removed and remains, the second insulation layer pattern 124 together with the high-k dielectric layer pattern 190 may serve as the gate insulation layer.

The gate structure 210, the impurity region 105 adjacent thereto and the ESD layer 160 may form a transistor. That is, the impurity region 105 and the ESD layer 160 may serve as a source/drain region of the transistor.

Referring to FIG. 8, a second insulating interlayer 220 may be formed on the first insulating interlayer 180, the resistor structure 142 and the gate structure 210, and a second opening 222 may be formed through the second insulating interlayer 220 to expose a top surface of the resistor structure 142, and a third opening 224 may be formed through the first and second insulating interlayers 180 and 220 and the etch stop layer 170 to expose a top surface of the ESD layer 160.

The second insulating interlayer 220 may include, e.g., silicon oxide. In some embodiments, the second insulating interlayer 220 may include a material, which is included in the first insulating interlayer 180.

The second and third openings 222 and 224 may be formed by forming a photoresist pattern on the second insulating interlayer 220 and dry etching the second insulating interlayer 220 using the photoresist pattern as an etching mask. An upper portion of the ESD layer 160 may be removed to form a recess.

In an example embodiment, a plurality of second openings 222 may be formed to expose top surfaces of the resistor structure 142.

Referring to FIG. 9, first and second metal silicide patterns 232 and 234 may be formed on the exposed portions of the resistor structure 142 and the ESD layer 160, respectively.

A metal layer may be formed on the exposed top surface of the resistor pattern 132, the exposed top surface of the ESD layer 160, sidewalls of the second and third openings 222 and 224 and a top surface of the second insulating interlayer 220 and thermally treated so that a silicidation process in which the resistor pattern 132 and the ESD layer 160 may be reacted with the metal layer, may be performed. In an example embodiment, the heat treatment may be performed at a temperature of less than about 400° C.

Thus, a metal silicide layer may be formed on the top surfaces of the resistor pattern 132 and the ESD layer 160, and a portion of the metal layer that has not been reacted may be removed to form the first and second metal silicide patterns 232 and 234 on the resistor pattern 132 and the ESD layer 160, respectively. In some embodiments, the metal layer may include nickel, cobalt, platinum, etc., and thus the first and second metal silicide patterns 232 and 234 may include nickel silicide, cobalt silicide, platinum silicide, etc.

The heat treatment for forming the metal silicide layer may be performed at a relatively low temperature of less than about 400° C., so that damage to the high-k dielectric layer pattern 190 in the gate structure 210 caused by the high temperature may be reduced.

Referring to FIG. 10, first and second contact structures 272 and 274 may be formed to fill the second and third openings 222 and 224, respectively.

The first and second contact structures 272 and 274 may be formed by the following processes. After a first barrier layer may be formed on top surfaces of the first and second metal silicide patterns 232 and 234, sidewalls of the second and third openings 222 and 224 and a top surface of the second insulating interlayer 220, a first conductive layer may be formed on the first barrier layer to sufficiently fill remaining portions of the second and third openings 222 and 224, and the first conductive layer and the first barrier layer may be planarized until a top surface of the second insulating interlayer 220 may be exposed.

Thus, the first contact structure 272 may include a first barrier layer pattern 252 and a first conductive layer pattern 262 sequentially stacked on the first metal silicide pattern 232, and the second contact structure 274 may include a second barrier layer pattern 254 and a second conductive layer pattern 264 sequentially stacked on the second metal silicide pattern 234. The first barrier layer pattern 252 may surround a bottom and a sidewall of the first conductive layer pattern 262, and the second barrier layer pattern 254 may surround a bottom and a sidewall of the second conductive layer pattern 264.

The first and second metal silicide patterns 232 and 234 may be formed on the top surfaces of the resistor pattern 132 and the ESD layer 160 exposed by the second and third openings 222 and 224, respectively, and the first and second contact structures 272 and 274 may be formed to fill the second and third openings 222 and 224, so that the first and second contact structures 272 and 274 may be aligned with the first and second metal silicide patterns 232 and 234, respectively.

In some embodiments, bottom surfaces of the first and second contact structures 272 and 274 may contact top surfaces of the first and second metal silicide patterns 232 and 234, respectively, and the bottom surfaces of the first and second contact structures 232 and 234 may be disposed in areas same as or within area where the top surfaces of the first and second metal silicide patterns 232 and 234 are disposed respectively, if viewed in plan view.

In some embodiments, the first barrier layer may include a metal or a metal nitride, and the first conductive layer may include doped polysilicon, a metal, a metal nitride and/or a metal silicide.

Referring to FIG. 1 again, a third insulating interlayer 280 may be formed on the second insulating interlayer 220 and the first and second contact structures 272 and 274, and third and fourth contact structures 312 and 314 may be formed on the first and second contact structures 272 and 274, respectively, through the third insulating interlayer 280.

The third insulating interlayer 280 may include, e.g., silicon oxide. The third insulating interlayer 280 may include a single layer or a plurality of layers sequentially stacked on each other. In some embodiments, the third insulating interlayer 280 may include a material, which is included in the first and second insulating interlayers 180 and 220.

The third and fourth contact structures 312 and 314 may be formed by following processes. After sixth and seventh openings may be formed through the third insulating interlayer 280 to expose top surfaces of the first and second contact structures 272 and 274, a second barrier layer may be formed on the exposed top surfaces of the first and second contact structures 272 and 274, sidewalls of the sixth and seventh openings and a top surface of the third insulating interlayer 280, and the second conductive layer and the second barrier layer may be planarized until a top surface of the third insulating interlayer 280 may be exposed.

Thus, the third contact structure 312 may include a third barrier layer pattern 292 and a third conductive layer pattern 302 sequentially stacked on the first contact structure 272, and the fourth contact structure 314 may include a fourth barrier layer pattern 294 and a fourth conductive layer pattern 304 sequentially stacked on the second contact structure 274. The third barrier layer pattern 292 may surround a bottom and a sidewall of the third conductive layer pattern 302, and the fourth barrier layer pattern 294 may surround a bottom and a sidewall of the fourth conductive layer pattern 304.

In some embodiments, the second barrier layer may include a metal or a metal nitride, and the second conductive layer may include doped polysilicon, a metal, a metal nitride and/or a metal silicide.

After the formation of the impurity region 105 and the ESD layer 160, which may be performed at a high temperature, and the formation of the gate structure 210, which may be also performed at a high temperature, then the first and second metal silicide patterns 232 and 234 may be formed. Therefore damage to the first and second metal silicide patterns 232 and 234 that may be caused by the high temperature processes may be reduced.

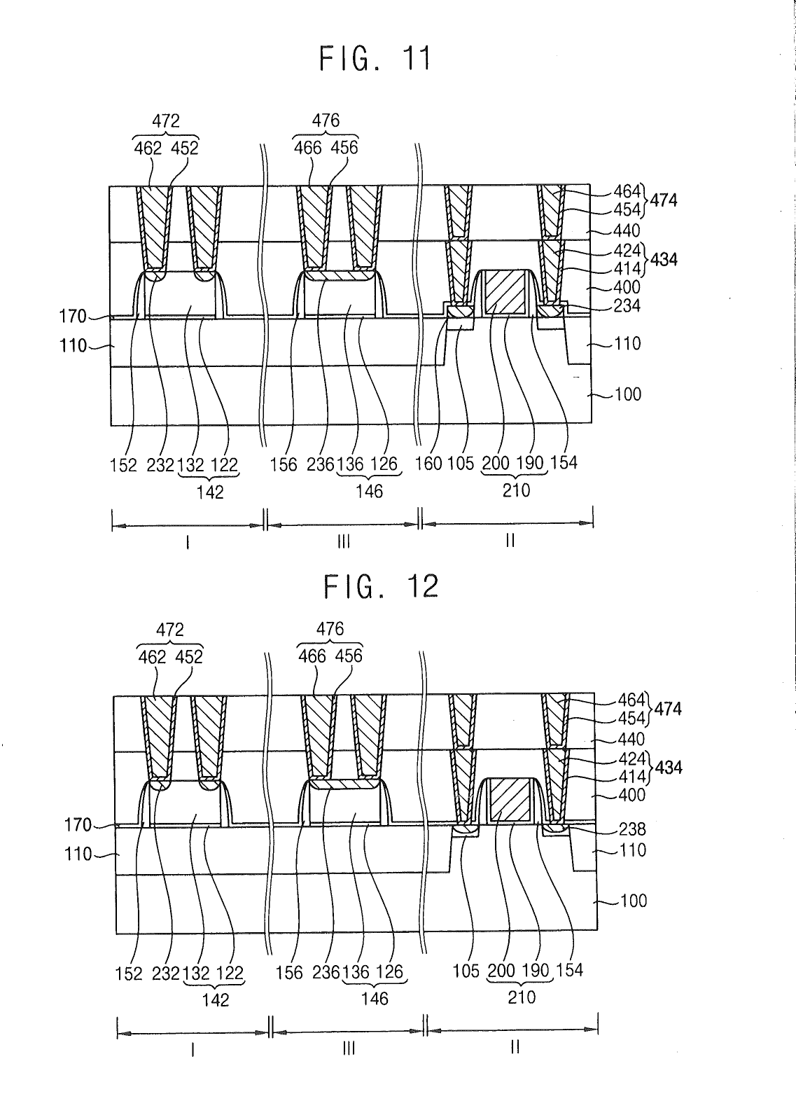

FIG. 11 is a cross-sectional view illustrating a semiconductor device in accordance with some embodiments.

Referring to FIG. 11, the semiconductor device may include a resistor structure 142, a gate structure 210, a fuse structure 146, an impurity region 105, an ESD layer 160, and first, second and third metal silicide patterns 232, 234 and 236.

The semiconductor device may further include sixth, fifth and eighth contact structures 472, 434 and 476 on the first, second and third metal silicide patterns 232, 234 and 236, respectively, and a seventh contact structure 474 on the fifth contact structure 434.

The substrate 100 may include a first region I, a second region II and a third region III. In some embodiments, resistors may be formed in the first region I, active devices for circuits may be formed in the second region II, and electrical fuses (E-fuses) may be formed in the third region III.

The fuse structure 146 may be formed on the substrate 100 in the third region III. In some embodiments, the fuse structure 146 may be formed on a field region of the substrate 100, i.e., on an isolation layer 110. In FIG. 11, only one fuse structure 146 is shown, however, a plurality of fuse structures 146 may be formed on the substrate 100 in the third region III.

The fuse structure 146 may include a third insulation layer pattern 126 and a fuse pattern 136 sequentially stacked on the substrate 100 in the third region

In some embodiments, the third insulation layer pattern 126 may include silicon oxide, and the fuse pattern 136 may include doped polysilicon.

A third spacer 156 may be formed on a sidewall of the fuse structure 146. The third spacer 156 may include, e.g., silicon nitride.

An etch stop layer 170 may be formed on sidewalls of the first, second and third spacers 152, 154 and 156, a sidewall and a top surface of the ESD layer 160, a top surface of the isolation layer 110 and a top surface of the substrate 100, however, in some cases, the formation of the etch stop layer 170 may be optional, thus it may be skipped.

The resistor structure 142, the gate structure 210, the fuse structure 146, the first, second and third spacers 152, 154 and 156, the ESD layer 160 and the etch stop layer 170 may be covered by a fourth insulating interlayer 400.

The first metal silicide pattern 232 may be formed at an upper portion of the resistor pattern 132, the second metal silicide pattern 234 may be formed at an upper portion of the ESD layer 160, and the third metal silicide pattern 236 may be formed at an upper portion of the fuse pattern 136. In an example embodiment, the first metal silicide pattern 232 may be formed at end portions of the resistor pattern 132, the second metal silicide pattern 234 may be formed through the ESD layer 160 to contact a top surface of the impurity region 105, and the third metal silicide pattern 236 may be formed at the whole upper portion of the fuse pattern 136.

In some embodiments, the first, second and third metal silicide patterns 232, 234 and 236 may include a metal silicide, e.g., nickel silicide, cobalt silicide, platinum silicide, etc.

The first, second and third metal silicide patterns 232, 234 and 236 may be formed after high temperature processes, e.g., the formation of the impurity region 105, the formation of the ESD layer 160, the formation of the gate structure 210. Thus damage to the first, second and third metal silicide patterns 232, 234 and 236 may be reduced and thus a semiconductor device including the first, second and third metal silicide patterns 232, 234 and 236 may have good electrical characteristics.

The fifth contact structure 434 may be formed through the fourth insulating interlayer 400 to contact the second metal silicide pattern 234. The fifth contact structure 434 may be aligned with the second metal silicide pattern 234. Thus, a bottom surface of the fifth contact structure 434 may be disposed in an area same as or within an area where a top surface of the second metal silicide pattern 234 is disposed, if viewed in plan view. The fifth contact structure 434 may include a fifth conductive layer pattern 424 and a fifth barrier layer pattern 414 on a bottom and a sidewall of the fifth conductive layer pattern 424. The fifth conductive layer pattern 424 may include, e.g., doped polysilicon, a metal, a metal nitride and/or a metal silicide, and the fifth barrier layer pattern 414 may include a metal or a metal nitride.

A fifth insulating interlayer 440 may be formed on the fourth insulating interlayer 400 and the fifth contact structure 434. The fifth insulating interlayer 440 may include, e.g., silicon oxide. In some embodiments, the fifth insulating interlayer 440 may include a material, which is included in the fourth insulating interlayer 400.

The sixth and eighth contact structures 472 and 476 may be formed through the fourth and fifth insulating interlayers 400 and 440 to contact the first and third metal silicide patterns 232 and 236. In some embodiments, the sixth contact structure 472 may include a sixth conductive layer pattern 462 and a sixth barrier layer pattern 452 on a bottom and a sidewall of the sixth conductive layer pattern 462, and the eighth contact structure 476 may include an eighth conductive layer pattern 466 and an eighth barrier layer pattern 456 on a bottom and a sidewall of the eighth conductive layer pattern 466.

The seventh contact structure 474 may be formed through the fifth insulating interlayer 440 to contact the fifth contact structure 434. In some embodiments, the seventh contact structure 474 may include a seventh conductive layer pattern 464 and a seventh barrier layer pattern 454 on a bottom and a sidewall of the seventh barrier layer pattern 464.

In some embodiments, the sixth, seventh and eighth conductive layer patterns 462, 464 and 466 may include the same material, e.g., doped polysilicon, a metal, a metal nitride and/or a metal silicide. In some embodiments, the sixth, seventh and eighth barrier layer patterns 452, 454 and 456 may include the same material, e.g., a metal or a metal nitride.

FIG. 12 is a cross-sectional view illustrating a semiconductor device in accordance with some embodiments.

Referring to FIG. 12, the semiconductor device may include a resistor structure 142, a gate structure 210, a fuse structure 146, an impurity region 105, and first, third and fourth metal silicide patterns 232, 236 and 238. The semiconductor device may further include sixth, eighth and fifth contact structures 472, 476 and 434 on the first, third and fourth metal silicide patterns 232, 236 and 238, respectively, and a seventh contact structure 474 on the fifth contact structure 434.

The semiconductor device may have no ESD layer, and thus may include the fourth metal silicide pattern 238 on the impurity region 105.

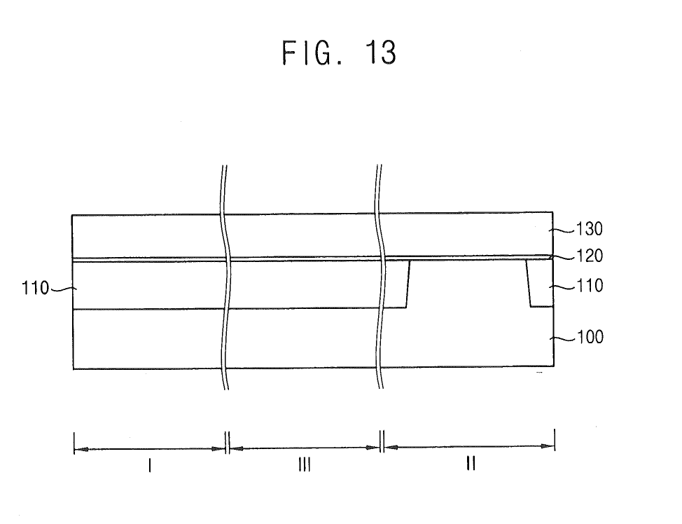

FIGS. 13 to 20 are cross-sectional views illustrating a method of manufacturing a semiconductor device in accordance with some embodiments.

Referring to FIG. 13, processes the same as or similar to those illustrated with reference to FIG. 3 may be performed. Thus, an insulation layer 120 and a doped polysilicon layer 130 may be sequentially formed on a substrate 100 and an isolation layer 110.

The substrate 100 may include a first region I, a second region II and a third region III. In some embodiments, resistors may be formed in the first region I, active devices of circuits, e.g., transistors may be formed in the second region II, and fuses, e.g., E-fuse, may be formed in the third region III.

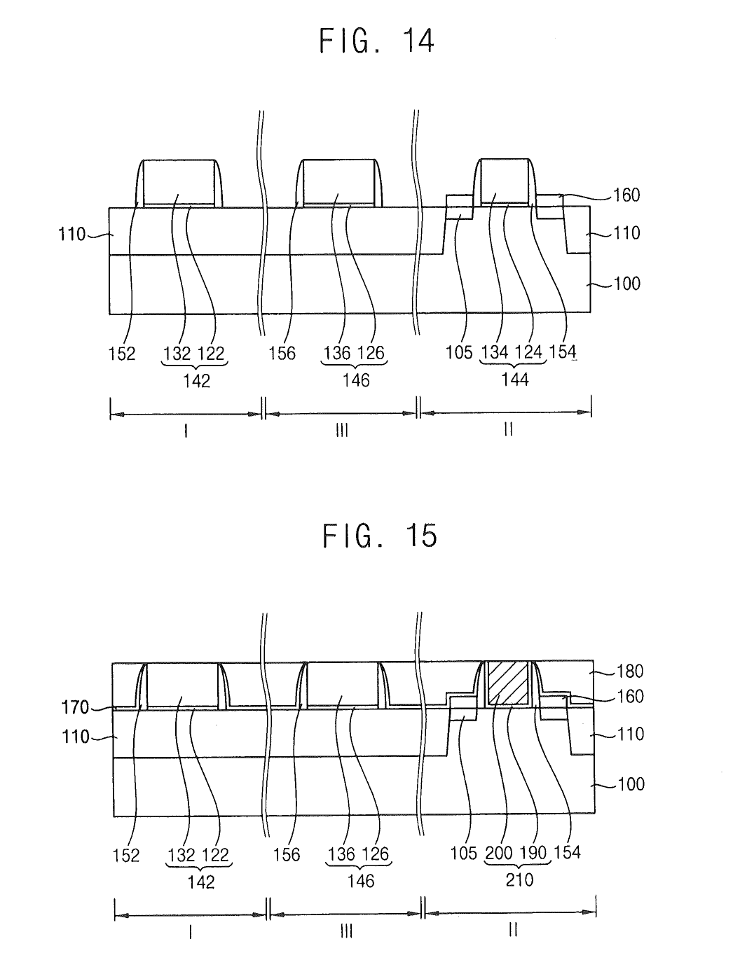

Referring to FIG. 14, processes the same as or similar to those illustrated with reference to FIG. 4 may be performed.

Thus, a resistor structure 142 including a first insulation layer pattern 122 and a resistor pattern 132 sequentially stacked on the substrate 100 in the first region I, a dummy gate structure 144 including a second insulation layer pattern 124 and a dummy gate electrode 134 sequentially stacked on the substrate 100 in the second region II, and a fuse structure 146 including a third insulation layer pattern 126 and a fuse pattern 136 sequentially stacked on the substrate 100 in the third region III may be formed. The third insulation layer pattern 126 may have a material, which is included in the first and second insulation layer patterns 122 and 124, e.g., silicon oxide, and the fuse pattern 136 may have a material, which is included in the resistor pattern 132, e.g., doped polysilicon.

In some embodiments, the resistor structure 142 and the fuse structure 146 may be formed on the field region of the substrate 100, i.e., on the isolation layer 110. In FIG. 14, only one resistor structure 142, only one dummy gate electrode 144 and only one fuse structure 146 are shown, however, a plurality of resistor structures 142, a plurality of dummy gate electrodes 144 and a plurality of fuse structures 146 may be also formed.

A first spacer 152 may be formed on a sidewall of the resistor structure 142, a second spacer 154 may be formed on a sidewall of the dummy gate structure 144, and a third spacer 156 may be formed on a sidewall of the fuse structure 146. The third spacer 156 may include a material included in the first and second spacers 152 and 154.

An impurity region 105 may be formed on the active region of the substrate 100 adjacent to the dummy gate structure 144, and an ESD layer 160 may be formed on the impurity region 105.

Referring to FIG. 15, processes the same as or similar to those illustrated with reference to FIGS. 5 to 7 may be performed.

Thus, after an etch stop layer 170 is formed on the resistor structure 142, the dummy gate structure 144, the fuse structure 146, the first, second and third spacers 152, 154 and 156 and the ESD layer 160, a first insulating interlayer 180 may be formed on the etch stop layer 170 to have a height sufficient to cover the resistor structure 142, the dummy gate structure 144, and the fuse structure 146.

Additionally, the dummy gate structure 144 having the second insulation layer pattern 124 and the dummy gate electrode 134 may be replaced by a gate structure 210 having the high-k dielectric layer pattern 190 and the gate electrode 200.

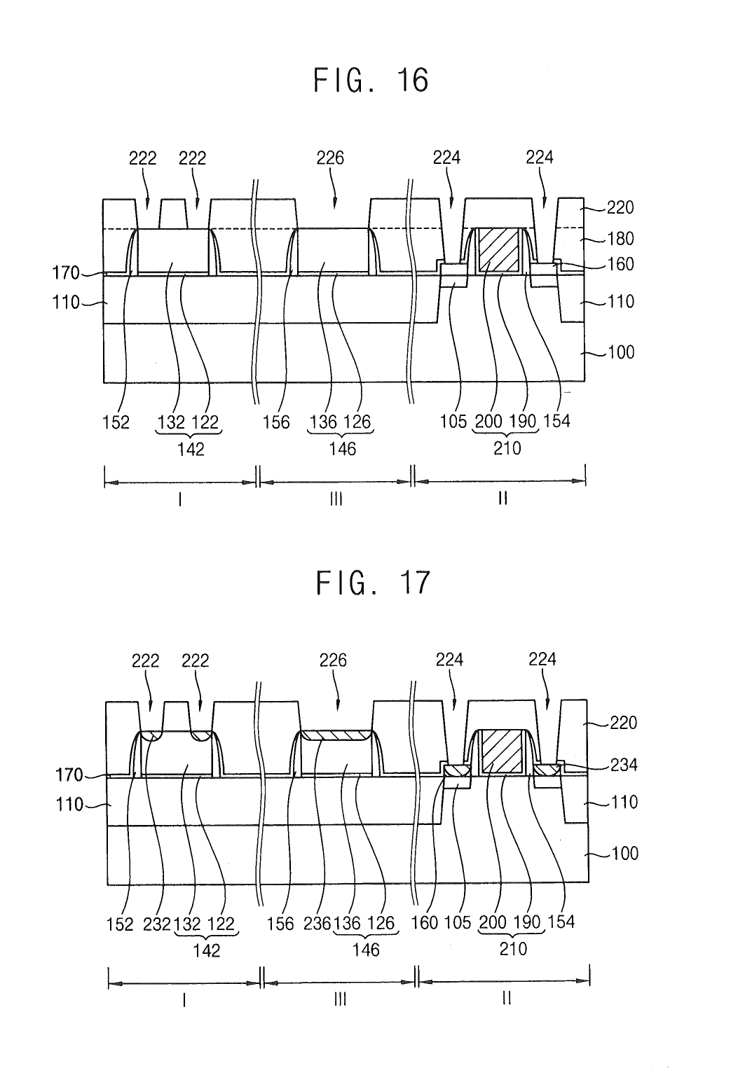

Referring to FIG. 16, processes the same as or similar to those illustrated with reference to FIG. 8 may be performed.

Thus, a second insulating interlayer 220 may be formed on the first insulating interlayer 180, the resistor structure 142, the gate structure 210 and the fuse structure 146, and a second opening 222 through the second insulating interlayer 220 and exposing a top surface of the resistor structure 142, a third opening 224 through the first and second insulating interlayers 180 and 220 and the etch stop layer 170 and exposing a top surface of the ESD layer 160, and a fourth opening 226 through the second insulating interlayer 220 and exposing a top surface of the fuse structure 146 may be formed.

In some embodiments, a plurality of second openings 222 may be formed to expose the top surface of the resistor structure 142, and one fourth opening 226 may be formed to expose the top surface of the fuse structure 146.

In some embodiments, the second insulating interlayer 220 may include a material included in the first insulating interlayer 180, and thus the first and second insulating interlayers 180 and 220 may be merged into one, which may be referred to as simply the second insulating interlayer 220.

Referring to FIG. 17, processes the same as or similar to those illustrated with reference to FIG. 9 may be performed.

Thus, first, second and third metal silicide patterns 232, 234 and 236 may be formed on the exposed portions of the resistor structure 142, the ESD layer 160 and the fuse structure 146, respectively.

The first, second and third metal silicide patterns 232, 234 and 236 may be weak to a high temperature, however, the first, second and third metal silicide patterns 232, 234 and 236 may be formed after processes accompanied by a high temperature, e.g., the formation of the impurity region 105 and the ESD layer 160 and the formation of the gate structure 210. Thus damage to first, second and third metal silicide patterns 232, 234 and 236 caused by the high temperature processes may be reduced.

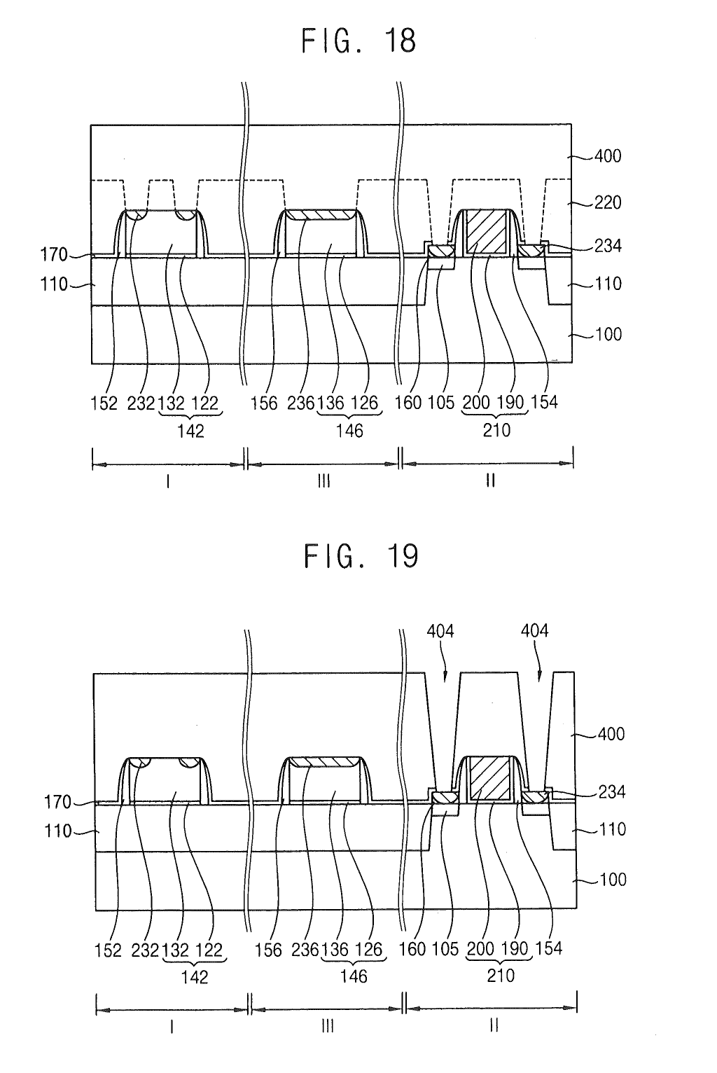

Referring to FIG. 18, a fourth insulating interlayer 400 may be formed on top surfaces of the first, second and third metal silicide patterns 232, 234 and 236 and a top surface of the second insulating interlayer 220 to sufficiently fill the second, third and fourth openings 222, 224 and 226.

The fourth insulating interlayer 400 may include, e.g., silicon oxide. In some embodiments, the fourth insulating interlayer 400 may include a material, which is included in the second insulating interlayer 220, and thus the second and fourth insulating interlayers 220 and 400 may be merged into one, which may be referred to as simply the fourth insulating interlayer 400.

Referring to FIG. 19, the fourth insulating interlayer 400 may be partially removed to form a fifth opening 404 exposing the second metal silicide pattern 234.

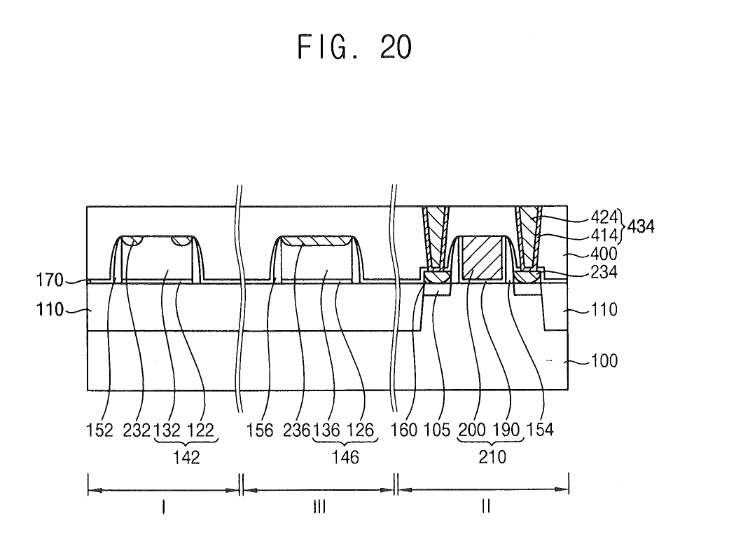

Referring to FIG. 20, a fifth contact structure 434 may be formed to fill the fifth opening 404.

After a third barrier layer may be formed on a top surface of the second metal silicide pattern 234, a sidewall of the fifth opening 404 and a top surface of the fourth insulating interlayer 400, a third conductive layer may be formed on the third barrier layer to sufficiently fill a remaining portion of the fifth opening 404, and the third conductive layer and the third barrier layer may be planarized until a top surface of the fourth insulating interlayer 400 may be exposed to form the fifth contact structure 434. Additionally, upper portions of the third conductive layer, the third barrier layer and the fourth insulating interlayer 400 may be removed so that the fifth contact structure 434 may have a desired height.

Thus, the fifth contact structure 434 may include a fifth barrier layer pattern 414 and a fifth conductive layer pattern 424 sequentially stacked on the second metal silicide pattern 234, and the fifth barrier layer pattern 414 may surround a bottom and a sidewall of the fifth conductive layer pattern 424.

In some embodiments, the third barrier layer may include a metal or a metal nitride, and the third conductive layer may include doped polysilicon, a metal, a metal nitride and/or a metal silicide.

Referring to FIG. 11 again, a fifth insulating interlayer 440 may be formed on the fourth insulating interlayer 400 and the fifth contact structures 434, sixth and eighth contact structures 472 and 476 may be formed on the first and third contact structures 232 and 236, respectively, through the fourth and fifth insulating interlayers 400 and 440, and a seventh contact structure 474 may be formed on the fifth contact structure 434 through the fifth insulating interlayer 440. In some embodiments, a plurality of sixth contact structures 472 may be formed to contact the first metal silicide patterns 232, respectively, and a plurality of eighth contact structures 476 may be formed to commonly contact the third metal silicide pattern 236.

The fifth insulating interlayer 440 may include, e.g., silicon oxide. In some embodiments, the fifth insulating interlayer 440 may include a material included in the fourth insulating interlayer 400.

The sixth contact structure 472 may include a sixth barrier layer pattern 452 and a sixth conductive layer pattern 462 sequentially stacked on the first metal silicide pattern 232, the eighth contact structure 476 may include an eighth barrier layer pattern 456 and an eighth conductive layer pattern 466 sequentially stacked on the third metal silicide pattern 236, and the seventh contact structure 474 may include a seventh barrier layer pattern 454 and a seventh conductive layer pattern 464 sequentially stacked on the fifth contact structure 434. The sixth barrier layer pattern 452 may surround a bottom and a sidewall of the sixth conductive layer pattern 462, the seventh barrier layer pattern 454 may surround a bottom and a sidewall of the seventh conductive layer pattern 464, and the eighth barrier layer pattern 456 may surround a bottom and a sidewall of the eighth conductive layer pattern 466.

In some embodiments, the sixth, seventh and eighth barrier layer patterns 452, 454 and 456 may include a metal or a metal nitride, and the sixth, seventh and eighth conductive layer patterns 462, 464 and 466 may include doped polysilicon, a metal, a metal nitride and/or a metal silicide.

The semiconductor devices and the methods of manufacturing the semiconductor devices may be applied to various types of memory devices including transistors and resistors. The semiconductor devices and the methods may be applied to memory devices having metal gate electrodes and polysilicon resistors in a logic region and fuses.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope is to be determined by the broadest permissible interpretation of the following claims and their equivalents, and shall not be restricted or limited by the foregoing detailed description.

What is claimed is:

1. A method of manufacturing a semiconductor device, comprising:
forming a resistor pattern and a dummy gate electrode on a substrate, the resistor pattern and the dummy gate electrode including doped polysilicon;
forming an impurity region at an upper portion of the substrate adjacent to the dummy gate electrode;
replacing the dummy gate electrode with a gate electrode; and then
forming first and second metal silicide patterns on the resistor pattern and the impurity region, respectively.

2. The method of claim 1, wherein replacing the dummy gate electrode with the gate electrode comprises:
forming a first insulating interlayer on the resistor pattern and the dummy gate electrode on the substrate;
removing the dummy gate electrode to form a first opening through the first insulating interlayer, the first opening exposing an upper surface of the substrate; and
forming the gate electrode on the exposed upper surface of the substrate in the first opening, the gate electrode including metal.

3. The method of claim 2, wherein forming the first and second metal silicide patterns comprises:
forming a second insulating interlayer on the first insulating interlayer, the resistor pattern and the gate electrode;
forming second and third openings exposing the resistor pattern and the impurity region, respectively, the second opening extending through the second insulating interlayer and the third opening extending through the first and second insulating interlayers;
forming a metal layer on the exposed resistor pattern and the impurity region; and
performing a silicidation process in which the metal layer reacts with the resistor pattern and the impurity region.

4. The method of claim 3, further comprising forming first and second contact structures in the second and third openings respectively.

5. The method of claim 2, further comprising forming a high-k dielectric layer pattern on a bottom surface and a sidewall of the first opening prior to forming the gate electrode, wherein the high-k dielectric layer pattern extends on a bottom surface and a sidewall of the gate electrode.

6. The method of claim 2, further comprising:
forming a fuse pattern on the substrate, the fuse pattern including doped polysilicon; and
forming a third metal silicide pattern on the fuse pattern, wherein forming the first insulating interlayer comprises forming the first insulating interlayer on the fuse pattern.

7. The method of claim 6, wherein forming the first, second and third metal silicide patterns comprises:
forming a second insulating interlayer on the first insulating interlayer, the resistor pattern, the gate electrode and the fuse pattern;
forming second and third openings exposing the resistor pattern and the fuse pattern respectively and a fourth opening exposing the impurity region, the second and third openings extending through the second insulating interlayer and the fourth opening extending through the first and second insulating interlayers;
forming a metal layer on the exposed resistor pattern, the impurity region and the fuse pattern; and
performing a silicidation process in which the metal layer reacts with the resistor pattern, the impurity region and the fuse pattern.

8. The method of claim 7, further comprising:
forming a third insulating interlayer on the second insulating interlayer to fill the second, third and fourth openings;
forming a fifth opening through the first, second and third insulating interlayers to expose the impurity region;
forming a first contact structure in the fifth opening;
forming a fourth insulating interlayer on the third insulating interlayer and the first contact structure;
forming sixth and seventh openings exposing the resistor pattern and the fuse pattern, respectively, and an eighth opening exposing the first contact structure, the sixth and seventh openings extending through the second, third and fourth insulating interlayers and the eighth opening extending through the fourth insulating interlayer; and
forming second, third and fourth contact structures in the sixth, seventh and eighth openings respectively.

9. The method of claim 8, wherein the first, second, third and fourth insulating interlayers include a same material.

10. The method of claim 1, further comprising performing a selective epitaxial growth (SEG) process using an upper portion of the impurity region as a seed layer to form an elevated source drain (ESD) layer on the impurity region, wherein forming the second metal silicide pattern comprises forming the second metal silicide pattern on the ESD layer.

11-15. (canceled)

16. A method of manufacturing an integrated circuit device, comprising:
forming a polysilicon pattern on a substrate in a first region;
forming a gate structure on the substrate in a second region;
forming an impurity region on the substrate adjacent to the gate structure; then
forming an insulating interlayer on the polysilicon pattern, the gate structure and the impurity region;
forming first and second openings extending through the insulating interlayer and exposing surfaces of the polysilicon pattern and the impurity region, respectively; and
forming first and second metal silicide patterns on the surfaces of the polysilicon pattern and the impurity region exposed by the first and second openings, respectively.

17. The method of claim 16, wherein forming the gate structure comprises forming the gate structure including a metal gate electrode.

18. The method of claim 16, wherein forming the gate structure comprises:
forming a dummy gate electrode on the substrate in the second region;
forming a first insulating interlayer on the dummy gate electrode, the first insulating interlayer exposing an upper surface of the dummy gate electrode;
removing the dummy gate electrode to form a gate opening in the first insulating layer; and
forming a metal gate electrode in the gate opening, wherein the second opening extends through the first insulating interlayer.

19. The method of claim 18, wherein forming the dummy gate electrode comprises:
forming a polysilicon layer on the substrate in the first and second regions; and
patterning the polysilicon layer to form the dummy gate electrode and the polysilicon pattern.

20. The method of claim 18, further comprising forming a high-k dielectric layer pattern conformally on a portion of the first insulating interlayer defining the gate opening prior to forming the metal gate electrode therein, wherein the high-k dielectric layer pattern extends between the first insulating interlayer and the metal gate electrode.

21. The method of claim 16, wherein forming the first and second metal silicide patterns comprises:
forming a metal layer contacting the surfaces of the polysilicon pattern and the impurity region exposed by the first and second openings respectively; and
performing a heat treatment to form the first and second metal silicide patterns through reactions of the metal layer with the polysilicon pattern and the impurity region, respectively.

22. The method of claim 16, wherein forming the impurity region comprises forming an elevated impurity region protruding from an upper surface of the substrate on the impurity region, and wherein forming the second metal silicide pattern comprises forming the second metal silicide pattern in the elevated impurity region.

23. The method of claim 16, further comprising forming an isolation layer in a field region on the substrate, wherein the polysilicon pattern extends over the isolation layer.

24. The method of claim 23, further comprising forming an insulating pattern on the isolation layer, wherein the insulating pattern contacts the isolation layer.

25. The method of claim 16, wherein the second opening exposes a portion of the surface of the polysilicon pattern and covers a remaining portion of the surface of the polysilicon pattern.
